(19) United States
(12) Patent Application Publication
(10) Pub. No.: US 2021/0066504 A1
(43) Pub. Date: Mar. 4, 2021

(54) THIN FILM TRANSISTOR AND MANUFACTURING METHOD THEREOF AND DISPLAY DEVICE

(71) Applicants: ORDOS YUANSHENG OPTOELECTRONICS CO., LTD., Ordos, Inner Mongolia (CN); BOE TECHNOLOGY GROUP CO., LTD., Beijing (CN)

(72) Inventors: Yanwei REN, Beijing (CN); Tianlei SHI, Beijing (CN); Wulijibaier TANG, Beijing (CN); Jingyi XU, Beijing (CN); Yanan YU, Beijing (CN); Chaochao SUN, Beijing (CN); Min LIU, Beijing (CN)

(21) Appl. No.: 17/054,711

(22) PCT Filed: Mar. 18, 2020
(86) PCT No.: PCT/CN2020/079924

§ 371 Date: Nov. 11, 2020

(30) Foreign Application Priority Data
Mar. 20, 2019 (CN) 201910214175.5

(51) Int. Cl. H01L 29/786; H01L 27/12; H01L 29/423; H01L 21/265; H01L 21/266; H01L 29/66

(52) U.S. Cl. CPC H01L 29/78636; H01L 27/1222; H01L 29/42384; H01L 29/78678; H01L 2029/42388; H01L 21/26513; H01L 21/266; H01L 29/66765; H01L 27/127

(57) ABSTRACT

The present disclosure provides a thin film transistor, a manufacturing method thereof, and a display device, and the thin film transistor of the present disclosure includes: a substrate; a gate, a gate insulating layer, an active layer, a source and drain layer sequentially provided on the substrate, and the source and drain layer is correspondingly provided at a first source contact region and a first drain contact region of the active layer. A planarization layer is provided between the gate insulating layer and the substrate, the planarization layer is in a same layer as the gate and in direct contact with the gate, and an upper surface of the planarization layer is flush with an upper surface of the gate.

### CROSS-REFERENCE TO RELATED APPLICATIONS

The present application claims the priority of Chinese Patent Application No. 201910214175.5, filed on Mar. 20, 2019, the content of which is incorporated herein by reference in its entirety.

### TECHNICAL FIELD

The present disclosure relates to the field of display technology, and particularly relates to a thin film transistor and a manufacturing method thereof, and a display device.

### BACKGROUND

During a conventional method for manufacturing a bottom gate thin film transistor, after a gate of the thin film transistor is formed on a glass substrate, other film layers of the thin film transistor are formed on the glass substrate sequentially. In this case, it is apparent that the gate formed on the glass substrate is formed as a convex structure upwards relative to the glass substrate itself. Therefore, the other film layers (e.g., an active layer) of the thin film transistor sequentially formed on the convex structure (i.e., the gate) may also be deformed and convex, such that carrier migration in the active layer is blocked when the thin film transistor operates, resulting in bad performance of the thin film transistor.

A new method for manufacturing a thin film transistor is provided in the present disclosure to solve the above problems.

### SUMMARY

The present disclosure provides a thin film transistor, which includes: a gate, a gate insulating layer, an active layer and a source and drain layer, which are sequentially provided on the substrate, the source and drain layer is provided at a first source contact region and a first drain contact region of the active layer, and a planarization layer is provided between the gate insulating layer and the substrate, the planarization layer is in a same layer as the gate and in direct contact with the gate, and an upper surface of the planarization layer is flush with an upper surface of the gate.

In some embodiments, a material of the planarization layer includes a transparent acrylic resin.

In some embodiments, a thickness of the gate insulating layer is in a range of 2000 Å to 5000 Å.

In some embodiments, a material of the active layer includes low temperature polysilicon.

The present disclosure further provides a method for manufacturing a thin film transistor including: sequentially forming a gate, a gate insulating layer, an active layer, a source and drain layer on a substrate, wherein the source and drain layer is provided at a first source contact region and a first drain contact region of the active layer; and after forming the gate, the method further includes forming a planarization layer such that the planarization layer is in a same layer as the gate and in direct contact with the gate, and an upper surface of the planarization layer is flush with an upper surface of the gate.

In some embodiments, the forming the gate and the planarization layer includes: forming a pattern of the gate on the substrate by a patterning process; depositing a planarization layer material on the substrate on which the gate is formed, forming a pattern of the planarization layer by performing exposure, development and curing processes on the planarization layer material, and exposing an upper surface of the gate by performing a dry etching process on the planarization layer such that the upper surface of the planarization layer is flush with the upper surface of the gate by the dry etching process.

In some embodiments, the dry etching process includes a descum process or an ashing process.

In some embodiments, the forming the gate insulating layer includes: depositing a gate insulating layer material on the substrate on which the gate and the planarization layer are formed, to form the gate insulating layer, wherein a thickness of the gate insulating layer is in a range of 2000 Å to 5000 Å.

In some embodiments, the forming the active layer includes: depositing an active layer material on the gate insulating layer, and forming a pattern of the active layer by a patterning process; and performing a first ion implantation process on the active layer.

In some embodiments, a material of the active layer includes low temperature polysilicon.

In some embodiments, the forming the source and drain layer includes: after the first ion implantation process is performed, forming a photoresist layer on the active layer by a patterning process such that the photoresist layer partially covers the active layer to expose the first source contact region and the first drain contact region of the active layer, and performing a second ion implantation process on the first source contact region and the first drain contact region of the active layer; and reducing a width of the photoresist layer by exposure and dry etching processes to expose a second source contact region and a second drain contact region of the active layer, and performing a third ion implantation process on the second source contact region and the second low-concentration drain contact region of the active layer; and removing the photoresist layer by an etching process, and forming the source and drain layer at the first source contact region and the first drain contact region of the active layer.

In some embodiments, a material of the planarization layer includes a transparent acrylic resin.

The present disclosure further provides a display device including the above thin film transistor.

### BRIEF DESCRIPTION OF THE DRAWINGS

FIG. 1 is a schematic diagram of a structure of a thin film transistor according to some embodiments of the present disclosure;

FIGS. 2 to 4 are cross-sectional views illustrating processes in a method for manufacturing a thin film transistor according to some embodiments of the present disclosure; and

FIG. 5 is a flow diagram of a method for manufacturing a thin film transistor according to some embodiments of the present disclosure.

### DETAILED DESCRIPTION

In order that those skilled in the art will better understand the technical solutions of the present disclosure, the present disclosure will be further described in detail with reference to the accompanying drawings and the specific embodiments.

In order to make the intention of the present embodiment better understood, the present embodiment will be described by taking a bottom gate thin film transistor as an example. Certainly, the thin film transistor of the present embodiment is not limited to the bottom gate thin film transistor, which is not limited herein.

The present embodiment provides a thin film transistor. The thin film transistor includes: a substrate 10; a gate 1, a gate insulating layer 3, an active layer 4; a source 9 electrically coupled to a first source contact region 5 of the active layer 4, and a drain 11 electrically coupled to a first drain contact region 6 of the active layer 4. The gate 1, the gate insulating layer 3 and the active layer 4 are sequentially provided on the substrate 10. Specifically, in the present embodiment, a planarization layer 2 is provided between the substrate 10 and the gate insulating layer 3. The planarization layer 2 is in a same layer as the gate 1 and is in direct contact with the gate 1. An upper surface of the planarization layer 2 is flush with an upper surface of the gate 1.

Since the planarization layer 2 of the present embodiment is in direct contact with the gate 1, and the upper surface of the planarization layer 2 is flush with the upper surface of the gate 1, an upper surface of the gate insulating layer 3 on the layer where the gate 1 is located is in a plane which is parallel to the substrate 10, such that upper and lower surfaces of the active layer 4 formed on the gate insulating layer 3 are substantially flat, thereby avoiding deformation and convex of the active layer 4 due to the fact that the other layers of the thin film transistor are directly formed on the substrate 10 having the gate 1 as a convex structure in the prior art. Further, the problem that the carrier migration in the active layer is blocked due to the convex of the active layer 4 when the thin film transistor operates, which influences the performance of the thin film transistor, is solved.

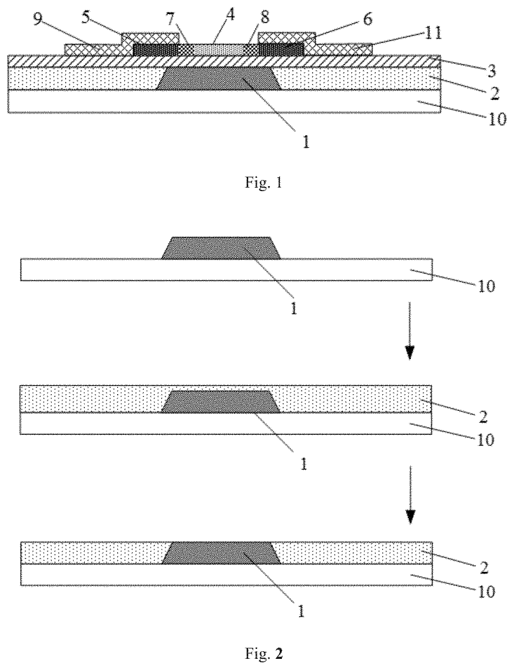

In addition, it should be noted that, FIG. 1 further shows that the gate 1 is provided opposite to the active layer 4 in the thin film transistor in the present embodiment, that is, an orthographic projection of the gate 1 on the substrate 10 at least partially covers an orthographic projection of the active layer 4 on the substrate 10. In this case, since the gate 1 itself is opaque, when the thin film transistor in the present embodiment is used for a liquid crystal display, light emitted from a backlight in the liquid crystal display cannot pass through the gate 1 to reach the active layer 4, thereby avoiding a leakage current due to photoelectric effect in the active layer 4 caused by light irradiation on the active layer 4. Meanwhile, a light shielding layer for shielding the active layer 4 is not required to be formed by an additional mask process in the present structure, such that the manufacturing procedure for the thin film transistor in the present embodiment is simplified, and the production cost is reduced.

In some embodiments, a thickness of the gate insulating layer 3 is in a range of 2000 Å ˜5000 Å.

It should be noted that, in the present embodiment, the gate insulating layer 3 with a larger thickness not only separates the active layer 4 from the gate 1 in the thin film transistor, but also ensures that there is a certain distance between the gate 1 and the source and the drain 9 and 11, thereby avoiding the interference between signals on the source 9, the drain 11 and the gate 1 in the thin film transistor and ensuring a better display effect of the display device including the thin film transistor of the present embodiment.

In some embodiments, a material of the planarization layer 2 includes a transparent acrylic resin. The transparent acrylic resin as a good flattening material is used for forming the planarization layer 2, such that the planarization layer 2 having a flat, smooth and uniform surface can be formed by a leveling process to further ensure that the planarization layer 2 and the gate 1 constitute a flat surface. Certainly, the material of the planarization layer 2 of the present embodiment is not limited to the aforementioned acrylic resin or transparent resin, and is not limited herein.

In some embodiments, a material of the active layer of the thin film transistor includes low temperature polysilicon, that is, the thin film transistor in the embodiment is a low temperature polysilicon thin film transistor. Certainly, the thin film transistor in the embodiment is not limited to the low temperature polysilicon thin film transistor, and is not repeated herein.

The present embodiment provides a method for manufacturing a thin film transistor, and the thin film transistor in the embodiment can be manufactured by the method in the present embodiment. Specifically, the manufacturing method includes sequentially forming a gate 1, a gate insulating layer 3, an active layer 4, a source 9 and a drain 11 on a substrate 10. The source 9 and the drain 11 are respectively formed at a first source contact region 5 and a first drain contact region 6 of the active layer 4. Particularly, the manufacturing method of the present embodiment further includes forming a planarization layer 2 between the substrate 10 and the gate insulating layer 3. The planarization layer 2 is formed in a same layer as the gate 1 and in direct contact with the gate 1. The upper surface of the planarization layer 2 is flush with the upper surface of the gate 1.

In order to make the method for manufacturing the thin film transistor clear in the embodiment, some specific manufacturing processes are described in the embodiment as follows.

In the present disclosure, a patterning process may include only a photolithography process, or the patterning process may include a photolithography process and an etching process, and the patterning process may further include another process for forming a predetermined pattern, such as printing, inkjet printing, etc. The photolithography process refers to a process of forming a pattern including steps of film formation, exposure, and development etc. with a photoresist, a mask plate, an exposure machine and the like. A corresponding patterning process may be selected according to a structure to be formed in the present disclosure.

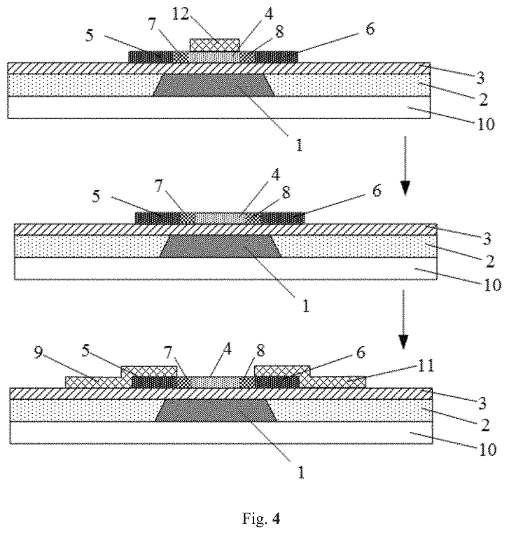

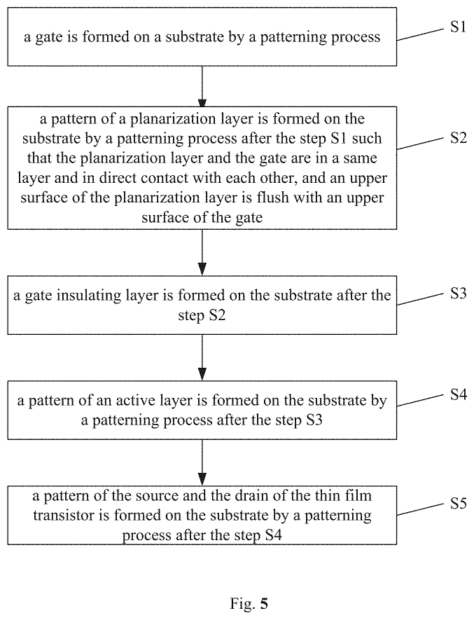

In some embodiments, a flow diagram of a method for manufacturing a thin film transistor is shown in FIGS. 2 to 4, and the method includes the following steps S1 to S5.

At step S1, a gate 1 is formed on a substrate 10 by a patterning process.

Specifically, the substrate 10 is made of a transparent material such as glass and is cleaned in advance. Specifically, a gate metal film is formed on the substrate 10 by sputtering, thermal evaporation, Plasma Enhanced Chemical Vapor Deposition (PECVD), Low Pressure Chemical Vapor Deposition (LPCVD), Atmospheric Pressure Chemical Vapor Deposition (APCVD), or Electron Cyclotron Resonance Chemical Vapor Deposition (ECR-CVD), a photoresist layer is formed on the gate metal film, and then a pattern of the gate 1 of the thin film transistor is formed by exposure, development, and etching processes.

A material of the gate metal film includes a conductive material such as metal (e.g., molybdenum, aluminum, titanium, and copper) and metal alloy (e.g., molybdenum niobium alloy, and aluminum neodymium alloy).

At step S2, a pattern of a planarization layer 2 is formed on the substrate 10 by a patterning process after the step S1. The planarization layer 2 and the gate 1 are in the same layer and in direct contact with each other. The upper surface of the planarization layer 2 is flush with the upper surface of the gate 1.

Specifically, as shown in FIG. 2, a planarization layer material is deposited on the substrate 10, and is subjected to exposure, development and curing processes to form a pattern of the planarization layer, which is subjected to dry etching to expose the upper surface of the gate 1 such that the upper surface of the planarization layer 2 is flush with the upper surface of the gate 1.

It should be noted that, the dry etching further includes a descum process or an ashing process to further ensure planarization of the upper surface of the planarization layer 2 and the upper surface of the gate 1 and to ensure the upper surface of the gate 1 to be exposed.

A material of the planarization layer 2 includes a transparent acrylic resin. Certainly, the material of the planarization layer 2 of the present embodiment is not limited to the aforementioned transparent acrylic resin, and is not limited herein.

At step S3, a gate insulating layer 3 is formed on the substrate 10 after the step S2.

Specifically, in the step, the gate insulating layer 3 may be formed by Plasma Enhanced Chemical Vapor Deposition, Low Pressure Chemical Vapor Deposition, Atmospheric Pressure Chemical Vapor Deposition, Electron Cyclotron Resonance Chemical Vapor Deposition, or sputtering.

A material of the gate insulating layer 3 includes silicon oxide, silicon nitride, or a composite material of silicon oxide and silicon nitride. Certainly, the material of the gate insulating layer 3 is not limited to the above.

A thickness of the gate insulating layer 3 is in a range of 2000 Å˜5000 Å.

It should be noted that, in the present embodiment, the gate insulating layer 3 with a larger thickness not only separates the active layer 4 from the gate 1 in the thin film transistor, but also ensures that there is a certain distance between the gate 1 and the source and the drain 9 and 11, thereby avoiding the interference between signals on the source 9, the drain 11 and the gate 1 in the thin film transistor and ensuring a better display effect of the display device including the thin film transistor of the present embodiment.

At step S4, a pattern of an active layer 4 is formed on the substrate 10 by a patterning process after the step S3.

Specifically, in the step, an active layer material is deposited on the gate insulating layer, a pattern of an active layer is formed by a patterning process performed on the active layer material, and then the active layer is subjected to a first ion implantation.

First, an amorphous silicon (a-Si) film may be formed by deposition including Plasma Enhanced Chemical Vapor Deposition and Low Pressure Chemical Vapor Deposition. And then, the amorphous silicon film is crystallized to be converted into a polysilicon (p-Si) film by excimer laser crystallization, metal induced crystallization or solid phase crystallization. The excimer laser crystallization and the metal induced crystallization are two methods for low temperature polysilicon and are common methods for converting amorphous silicon into polysilicon. However, the method for converting amorphous silicon into polysilicon in the present disclosure is not limited to the method of using low temperature polysilicon as long as the active layer 4 could be converted into a desired polysilicon film. After that, a pattern of the active layer 4 is formed. That is, a photoresist layer is formed on the polysilicon film, the photoresist layer is exposed and developed, and then the polysilicon film is dry etched to form a pattern of the active layer 4. Thereafter, the active layer 4 (p-Si) is first doped by ion implantation. The ion implantation includes an ion implantation method with a mass analyzer, an ion cloud implantation method without a mass analyzer, a plasma implantation method, or a solid diffusion implantation method. That is, in the present embodiment, the active layer 4 with good semiconductor properties is finally formed by performing multiple steps such as crystallization, doping, ion implantation, etc., on the low temperature polysilicon material.

At step S5, a pattern of the source 9 and the drain 11 of the thin film transistor is formed on the substrate 10 by a patterning process after the step S4.

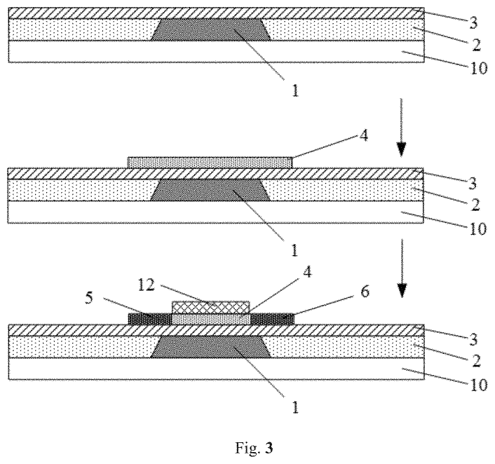

Specifically, in the step, as shown in FIG. 3, a photoresist layer 12 is formed on the active layer 4 by a patterning process after the first ion implantation has been performed. The photoresist layer 12 partially covers the active layer 4, such that the active layer 4 exposes the first source contact region 5 and the first drain contact region 6.

Then, a second ion implantation is performed on the first source contact region 5 and the first drain contact region 6 of the active layer 4, i.e., P-type doping or N-type doping, to determine a conductivity type of the channel region of the thin film transistor TFT.

Further, a width of the photoresist layer 12 is further reduced by exposure and dry etching to expose a second source contact region 7 and a second drain contact region 8 of the active layer 4.

It should be noted that, the thin film transistor of the present disclosure adopts a bottom gate structure. A required doped region is formed by controlling the width of the photoresist (PR) layer by exposure and dry etching, which could accurately control the ion implantation amount and is a simple and easy doping method.

A third ion implantation (i.e., LDD doping) is performed on the second source contact region 7 and the second drain contact region 8 of the active layer 4. The LDD doping is a doping of a lower concentration, so as to enhance ohmic contact between the active layer 4 and the source and the drain 9 and 11 to prevent hot carrier effect of the thin film transistor and to ensure good ohmic contact between the active layer 4 and the source and the drain 9 and 11.

Further, the photoresist layer 12 is removed by etching, and the source 9 and the drain 11 are formed at corresponding positions in the first source contact region 5 and the first drain contact region 6 of the active layer 4. Specifically, the source 9 and the drain 11 may be formed by the following steps. A source metal film and a drain metal film may be formed by sputtering, thermal evaporation, Plasma Enhanced Chemical Vapor Deposition, Low Pressure Chemical Vapor Deposition, Atmospheric Pressure Chemical Vapor Deposition, or Electron Cyclotron Resonance Chemical Vapor Deposition; a photoresist layer is formed on the source metal film and the drain metal film, and then a pattern of the source 9 and the drain 11 of the thin film transistor is formed by exposure, development, and etching processes. A material of the source metal film and the drain metal film includes a conductive material such as metal (e.g., molybdenum, aluminum, titanium, and copper) and metal alloy (e.g., molybdenum niobium alloy, and aluminum neodymium alloy).

As above, the thin film transistor is completed.

In other embodiments, the planarization layer 2 is formed by a leveling process instead of the patterning process, which is the only difference from the above embodiments in the step S2. Specifically, a pattern of the planarization layer 2 is formed on the substrate 10 by the leveling process after the step S1. The planarization layer 2 and the gate 1 are in the same layer and in direct contact with each other, and the upper surface of the planarization layer 2 is flush with the upper surface of the gate 1.

Specifically, a material of the planarization layer 2 includes a transparent acrylic resin. The transparent acrylic resin as a good flattening material is used for forming the planarization layer 2, such that the planarization layer 2 having a flat, smooth and uniform surface may be formed by the leveling process to further ensure that the planarization layer 2 and the gate 1 constitute a flat surface.

The remaining steps for manufacturing the planarization layer by the leveling process and forming the thin film transistor are the same as those of the above described embodiments, and will not be repeated.

Since the method for manufacturing the thin film transistor in the embodiment includes forming the planarization layer 2 such that the planarization layer 2 and the gate 1 are in the same layer and in direct contact with each other, and the upper surface of the planarization layer 2 is flush with the upper surface of the gate 1, the upper surface of the gate insulating layer 3 on the layer where the gate 1 is located is in a plane which is parallel to the substrate 10, such that the upper and lower surfaces of the active layer 4 formed on the gate insulating layer 3 are substantially flat, thereby avoiding the deformation and convex of the active layer 4 due to the fact that the other layers of the thin film transistor are directly formed on the substrate 10 having the gate 1 as a convex structure in the prior art. Further, the problem that the carrier migration in the active layer is blocked due to the convex of the active layer 4 when the thin film transistor operates, which influences the performance of the thin film transistor, is solved.

A display device is provided in the present disclosure. The display device includes the thin film transistor in the above embodiments. Since the display device in the present disclosure includes the above thin film transistor, and the display device has a better display effect.

The display device may be a liquid crystal display device or an electroluminescent display device, such as any product or component having a display function, for example, a liquid crystal panel, electronic paper, an OLED panel, a mobile phone, a tablet computer, a television, a display, a notebook computer, a digital photo frame, a navigator, and the like.

It should be understood that the above embodiments are merely exemplary embodiments employed to illustrate the principles of the present disclosure, and the present disclosure is not limited thereto. It will be apparent to those skilled in the art that various changes and modifications can be made therein without departing from the spirit and scope of the disclosure, and these changes and modifications are to be considered within the scope of the disclosure.

1. A thin film transistor, comprising:
a substrate; and
a gate, a gate insulating layer, an active layer and a source and drain layer, which are sequentially provided on the substrate, wherein the source and drain layer is provided at a first source contact region and a first drain contact region of the active layer;
wherein a planarization layer is provided between the gate insulating layer and the substrate, the planarization layer is in a same layer as the gate and the planarization layer is in direct contact with the gate, and an upper surface of the planarization layer is flush with an upper surface of the gate.

2. The thin film transistor of claim 1, wherein a material of the planarization layer comprises a transparent acrylic resin.

3. The thin film transistor of claim 1, wherein a thickness of the gate insulating layer is in a range of 2000 Å to 5000 Å.

4. The thin film transistor of claim 1, wherein a material of the active layer comprises low temperature polysilicon.

5. A method for manufacturing a thin film transistor, comprising:
sequentially forming a gate, a gate insulating layer, an active layer, a source and drain layer on a substrate, wherein the source and drain layer is provided at a first source contact region and a first drain contact region of the active layer;
wherein after forming the gate, the method further comprises forming a planarization layer such that the planarization layer is in a same layer as the gate and in direct contact with the gate, and an upper surface of the planarization layer is flush with an upper surface of the gate.

6. The method of claim 5, wherein the forming the gate and the planarization layer comprises:
forming a pattern of the gate on the substrate by a patterning process;
depositing a planarization layer material on the substrate on which the gate is formed, forming a pattern of the planarization layer by performing exposure, development and curing processes on the planarization layer material, and exposing an upper surface of the gate by performing a dry etching process on the planarization layer such that the upper surface of the planarization layer is flush with the upper surface of the gate by the dry etching process.

7. The method of claim 6, wherein the dry etching process comprises a descum process or an ashing process.

8. The method of claim 6, wherein the forming the gate insulating layer comprises:
depositing a gate insulating layer material on the substrate on which the gate and the planarization layer are formed, to form the gate insulating layer, wherein a thickness of the gate insulating layer is in a range of 2000 Å to 5000 Å.

9. The method of claim 6, wherein the forming the active layer comprises:
depositing an active layer material on the gate insulating layer, and forming a pattern of the active layer by a patterning process; and
performing a first ion implantation process on the active layer.

10. The method of claim 9, wherein a material of the active layer comprises low temperature polysilicon.

11. The method of claim 9, wherein the forming the source and drain layer comprises:
after the first ion implantation process is performed, forming a photoresist layer on the active layer by a patterning process such that the photoresist layer partially covers the active layer to expose the first source contact region and the first drain contact region of the active layer, and performing a second ion implantation process on the first source contact region and the first drain contact region of the active layer; and
reducing a width of the photoresist layer by exposure and dry etching processes to expose a second source contact region and a second drain contact region of the active layer, and performing a third ion implantation process on the second source contact region and the second drain contact region of the active layer; and
removing the photoresist layer by an etching process, and forming the source and drain layer at the first source contact region and the first drain contact region of the active layer.

12. The method of claim 5, wherein a material of the planarization layer comprises a transparent acrylic resin.

13. A display device, comprising a thin film transistor, which comprises:
a substrate; and
a gate, a gate insulating layer, an active layer and a source and drain layer, which are sequentially provided on the substrate, wherein the source and drain layer is provided at a first source contact region and a first drain contact region of the active layer;
wherein a planarization layer is provided between the gate insulating layer and the substrate, the planarization layer is in a same layer as the gate and the planarization layer is in direct contact with the gate, and an upper surface of the planarization layer is flush with an upper surface of the gate.

14. The display device of claim 13, wherein a material of the planarization layer comprises a transparent acrylic resin.

15. The display device of claim 13, wherein a thickness of the gate insulating layer is in a range of 2000 Å to 5000 Å.

16. The display device of claim 13, wherein a material of the active layer comprises low temperature polysilicon.
